(19) United States
(12) Patent Application Publication
(10) Pub. No.: US 2026/0068449 A1
(43) Pub. Date: Mar. 5, 2026

(54) DISPLAY PANEL, METHOD FOR PREPARING DISPLAY PANEL, AND DISPLAY DEVICE

(71) Applicant: TCL CHINA STAR OPTOELECTRONICS TECHNOLOGY CO., LTD., Shenzhen (CN)

(72) Inventors: Libin ZHOU, Shenzhen (CN); Rui ZHAO, Shenzhen (CN); Zhuo ZHANG, Shenzhen (CN)

(73) Assignee: TCL CHINA STAR OPTOELECTRONICS TECHNOLOGY CO., LTD., Shenzhen (CN)

(21) Appl. No.: 19/004,297

(22) Filed: Dec. 28, 2024

Related U.S. Application Data
(63) Continuation of application No. PCT/CN2024/119865, filed on Sep. 20, 2024.

(30) Foreign Application Priority Data
Sep. 3, 2024 (CN) 202411237254.5

(51) Int. Cl. H10K 59/126; H10K 59/12; H10K 59/122; H10K 59/123; H10K 59/80

(52) U.S. Cl. CPC H10K 59/126; H10K 59/122; H10K 59/123; H10K 59/80516; H10K 59/1201

(57) ABSTRACT

Embodiments of this application provide a display panel and a display device. The display panel includes: an array substrate including a first metal layer, wherein the first metal layer includes a first auxiliary electrode and a first anode; a pixel defining layer; a light emitting layer including a first light emitting unit; a second metal layer including a cathode; and a shielding layer located between the pixel defining layer and the light emitting layer. The shielding layer connects to the first light emitting unit but does not connect to the cathode. The first auxiliary electrode includes a first undercut structure, and the first light emitting unit breaks at the first undercut structure.

### CROSS-REFERENCE TO RELATED APPLICATIONS

This application is a continuation of International Application No. PCT/CN2024/119885, filed on Sep. 20, 2024, which claims priority to and the benefit of Chinese Patent Application No. 202411237254.5, filed on Sep. 3, 2024. The disclosures of the aforementioned applications are incorporated herein by reference in their entireties.

### TECHNICAL FIELD

The present application relates to display technologies, and in particular, to a display panel, a method for preparing a display panel, and a display device.

### BACKGROUND

Organic light-emitting diode (OLED) display components are widely used in various fields due to their lightweight, wide viewing angle, fast response, low temperature resistance, high emitting efficiency, and ability to prepare curved flexible displays. In order to realize full color display, red, blue, and green sub-pixels of the OLED display component are separately formed through multiple fine metal mask processes; however, due to limitations imposed by the size and precision of a mask plate, it is necessary to reserve a certain amount of fabrication error space when forming the sub-pixels, which leads the OLED display component formed by adopting the mask plate having a low pixel density, and the fine metal mask process is difficult to apply to manufacture the large-size display components.

### SUMMARY

In view of the above, this application provides a display panel and a display device, aiming to solve technical problems that the OLED display component has a low pixel density and the fine metal mask process is difficult to apply to manufacture the large-size display components.

To solve the technical problems aforementioned, this application provides technical solutions as follows:

According to a first aspect, this application provides a display panel. The display panel includes: an array substrate including a first metal layer, wherein the first metal layer includes a first auxiliary electrode, and a first anode located on a side of the first auxiliary electrode; a pixel defining layer located on a side of the array substrate and covering the first metal layer; the pixel defining layer including a first auxiliary opening and a first pixel opening, wherein a part of the first auxiliary electrode is exposed through the first auxiliary opening, and a part of the first anode is exposed through the first pixel opening; a light emitting layer including a first light emitting unit and located on a side of the pixel defining layer away from the array substrate, wherein the first light emitting unit connects to the first anode and the first auxiliary electrode, respectively; and a second metal layer including a cathode, wherein the cathode is located on a side of the light emitting layer away from the pixel defining layer. The display panel further includes a shielding layer located between the pixel defining layer and the light emitting layer, wherein the shielding layer connects to the first light emitting unit but does not connect to the cathode. The first auxiliary electrode includes a first undercut structure positioned corresponding to the first auxiliary opening, and the first light emitting unit breaks at the first undercut structure.

According to a second aspect, this application further provides a display device, the display device includes the display panel as mentioned above.

According to a third aspect, this application further provides a method for preparing a display panel including: forming an array substrate, wherein the array substrate includes a first metal layer, and the first metal layer includes a first auxiliary electrode, a first anode located on a side of the first auxiliary electrode, a second auxiliary electrode, and a second anode located on a side of the second auxiliary electrode;
forming a pixel defining layer on a side of the array substrate, wherein the pixel defining layer covers the first metal layer and includes a first auxiliary opening, a first pixel opening, a second auxiliary opening, and a second pixel opening, parts of the first auxiliary electrode and the second auxiliary electrode are exposed through the first auxiliary opening and the second auxiliary opening, respectively, and remaining parts of the pixel defining layer within the first pixel opening and the second pixel opening cover the first anode and the second anode, respectively;
forming a patterned shielding layer on a side of the pixel defining layer away from the array substrate, wherein parts of the first auxiliary electrode and the second auxiliary electrode are exposed through the shielding layer;
etching the first auxiliary electrode and the second auxiliary electrode, respectively, to obtain a first undercut structure and a second undercut structure;
removing all of the remaining part of the pixel defining layer within the first pixel opening to expose the first anode and a part of the remaining part of the pixel defining layer within the second pixel opening by a dry etching process, wherein the rest of the remaining part of the pixel defining layer within the second pixel opening covers the second anode;
forming a first initial light emitting layer and a first initial cathode layer on the first initial light emitting layer by a whole surface evaporation process, and removing remaining parts of the first initial light emitting layer and the first initial cathode layer by a photolithography process to obtain a first light emitting unit and a first cathode portion, respectively, wherein the first light emitting unit is connected to the first anode and the first auxiliary electrode, respectively, and breaks at the first undercut structure, and the first cathode portion is connected to the first auxiliary electrode;
removing the whole remaining part of the pixel defining layer within the second pixel opening to expose the second anode by a dry etching process; and
forming a second initial light emitting layer and a second initial cathode layer on the second initial light emitting layer by a whole surface evaporation process, and removing remaining parts of the second initial light emitting layer and the second initial cathode layer by a photolithography process to obtain a second light emitting unit and a second cathode portion, respectively, wherein the second light emitting unit is connected to the second anode and the second auxiliary electrode, respectively, and breaks at the second undercut structure, and the second cathode portion is connected to the second auxiliary electrode.

### BRIEF DESCRIPTION OF THE DRAWINGS

In order to more clearly illustrate the technical solutions in embodiments of the present application, the accompanying drawings to be used in the description of the embodiments will be briefly introduced below. It will be apparent that the drawings in the following description are merely illustrative of some embodiments of the present application, and that other drawings may be made by the skilled person in the art without involving any inventive effort.

FIG. 1 is a schematic section diagram of a display panel according to one or more embodiments of the present application.

FIG. 2 is a schematic flowchart of a method for preparing a display panel according to one or more embodiments of the present application.

FIG. 3 is a section diagram of a first intermediate structure according to one or more embodiments of the present application.

FIG. 4 is a section diagram of the first intermediate structure shown in FIG. 3 after being etched through a first dry etching process.

FIG. 5 is a section diagram of the first intermediate structure shown in FIG. 4 with a first light emitting unit and a first cathode portion formed.

FIG. 6 is a section diagram of the first intermediate structure shown in FIG. 5 with a second light emitting unit and a second cathode portion formed.

FIG. 7 is a section diagram of a second intermediate structure obtained after forming a third light emitting unit and a third cathode portion on the first intermediate structure shown in FIG. 6.

### REFERENCE NUMBERS

100, display panel; 110, array substrate; 120, pixel defining layer; 130, shielding layer; 140, light emitting layer; 150, second metal layer; 10, first metal layer; 11, first auxiliary electrode; 12, first anode; 13, second auxiliary electrode; 14, second anode; 15, third auxiliary electrode; 16, third anode; 101, first electrode layer; 102, second electrode layer; 103, third electrode layer; 111, first undercut structure; 121, second undercut structure; 131, third undercut structure; 112, first undercut groove; 1121, first sub-groove; 1122, second sub-groove; 122, second undercut groove; 1221, third sub-groove; 1222, fourth sub-groove; 132, third undercut groove; 1321, fifth sub-groove; 1322, sixth sub-groove; 104, light-shielding layer; 105, transistor; 1041, first light-shielding portion; 1042, second light-shielding portion; 21, first auxiliary opening; 22, first pixel opening; 23, second auxiliary opening; 24, second pixel opening; 25, third auxiliary opening; 26, third pixel opening; 31, first shielding unit; 32, second shielding unit; 33, third shielding unit; 34, first opening; 35, second opening; 27, third opening; 28, fourth opening; 41, first light emitting unit; 42, second light emitting unit; 43, third light emitting unit; 411, first light emitting portion; 412, second light emitting portion; 421, third light emitting portion; 422, fourth light emitting portion; 431, fifth light emitting portion; 432, sixth light emitting portion; 401, first gap; 402, second gap; 50, cathode; 51, first cathode portion; 52, second cathode portion; 53, third cathode portion; 160, encapsulation layer; 1001, first intermediate structure; 1002, second intermediate structure.

### DETAILED DESCRIPTION

The technical solution in the embodiments of this application will be clearly and completely described with reference to the accompanying drawings. It will be apparent that the described embodiments are only part of the embodiments of this application, and not all of them. Based on the embodiments of this application, all other embodiments obtained by the skilled person in the art without involving any inventive effort are within the scope of the present application.

In the description of this application, it should be understood that orientation or position relationships indicated by the terms such as “length”, “width”, “thickness”, “up”, “down”, “front”, “back”, “left”, “right”, “top”, “bottom”, “inside”, “outside” are based on orientation or position relationships shown in the accompanying drawings, to facilitate the description of the present application and simplify the description only, rather than indicating or implying that the mentioned apparatus or element must have a particular orientation or must be constructed and operated in a particular orientation. Therefore, such terms should not be construed as limiting of the present application. In addition, the term “first”, “second”, etc. is only used for descriptive purposes, and cannot be understood as indicating or implying relative importance or implicitly indicating the number of technical features indicated. Thus, the characteristics that are defined as “first” or “second” may explicitly or implicitly include one or more of the characteristics. In the description of this application, “multiple” means two or more, “at least one” means one, two or more, unless otherwise specifically limited. In the description of this application, “vertical” means completely vertical to 90° or almost completely vertical, for example, any angle within a range of 80° to 100° is considered as “vertical”; similarly, “parallel” means completely parallel or almost completely parallel, for example, any angle within 10° refer to “completely parallel” is considered as “parallel”.

In this application, it should be noted that an arrow marked X is used to indicate a thickness direction of the display panel, and the thickness direction is a direction of a pixel layer toward a light control layer. The thickness direction X of the display panel is introduced to facilitate the description of the structural positional relationships of the display panel, thus facilitating the understanding of its structure.

It should also be noted that in the accompanying drawings, dotted arrows are used to indicate a main light direction of the pixels.

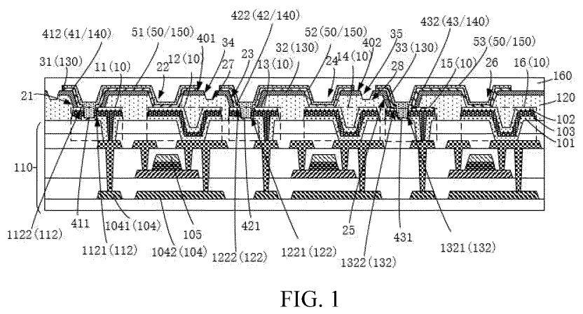

Referring to FIG. 1, this application provides a display panel 100, and the display panel 100 can be an OLED display panel, such as a low temperature poly-silicon (LTPS), an indium gallium zinc oxide (IGZO), an active-matrix organic light-emitting diode (AMOLED), and other types of OLED display panels.

The display panel 100 includes an array substrate 110, a pixel defining layer 120, a shielding layer 130, a light emitting layer 140, and a second metal layer 150. The array substrate 110, the pixel defining layer 120, the shielding layer 130, the light emitting layer 140, and the second metal layer 150 are stacked in sequence.

In some embodiments of this application, the array substrate 110 includes a first metal layer 10, which includes a first auxiliary electrode 11, a first anode 12 located on a side of the first auxiliary electrode 11, a second auxiliary electrode 13, a second anode 14 located on a side of the second auxiliary electrode 13, a third auxiliary electrode 15, and a third anode 16 located on a side of the third auxiliary electrode 15.

In some embodiments of this application, the first anode 12 is positioned between the first auxiliary electrode 11 and the second auxiliary electrode 13, the second auxiliary electrode 13 is positioned between the first anode 12 and the second anode 14, the second anode 14 is positioned between the second auxiliary electrode 13 and the third auxiliary electrode 15, and the third anode 16 is positioned on the side of the third auxiliary electrode 15 away from the second anode 14. In other embodiments of this application, an arrangement order of the first auxiliary electrode 11, first anode 12, second auxiliary electrode 13, second anode 14, third auxiliary electrode 15, and third anode 16 is not limited and can be adjusted according to an actual situation.

In some embodiments of this application, the first metal layer 10 may also include additional auxiliary electrodes and anodes.

In some embodiments of this application, the first auxiliary electrode 11, first anode 12, second auxiliary electrode 13, second anode 14, third auxiliary electrode 15, and third anode 16 are arranged in the same layer and made of the same material. The first auxiliary electrode 11 is used as an example to illuminate the film structure of the first auxiliary electrode 11, the first anode 12, the second auxiliary electrode 13, the second anode 14, the third auxiliary electrode 15, and the third anode 16. The first anode 12, the second anode 14, and the third anode 16 each can form an electric field with a cathode to realize a display of the display panel, and the first auxiliary electrode 11, the second auxiliary electrode 13, and the third auxiliary electrode 15 each can be in contact with the cathode to reduce an impedance of the cathode, enhance an electrical performance of the display panel, and lower a power consumption of the display panel.

The first auxiliary electrode 11 includes a first electrode layer 101, a second electrode layer 102, and a third electrode layer 103 located between the first electrode layer 101 and the second electrode 102. The first electrode layer 101, the second electrode layer 102, and the third electrode layer 103 are stacked in sequence in a stacking direction of the array substrate 110 and the pixel defining layer 120.

The material of the first electrode layer 101 and the material of the second electrode layer 102 may be the same or different from each other; however, the material of the first electrode layer 101 and the material of the second electrode layer 102 are both different from the material of the third electrode layer 103. In some embodiments of this application, the first electrode layer 101 and the second electrode layer 102 are made of indium tin oxide (ITO) or indium zinc oxide (IZO), while the third electrode layer 103 is made of silver (Ag) metal. The first auxiliary electrode 11 features a sandwich structure with different materials, which facilitates the formation of a first undercut structure 111 characterized by retracted upper and lower layers and a protruding middle layer.

One end of the third electrode layer 103 of the first auxiliary electrode 11 protrudes from the first electrode layer 101 and second electrode layer 102 of the first auxiliary electrode 11 to form the first undercut structure 111 (shown in FIG. 4). Similarly, one end of the third electrode layer 103 of the second auxiliary electrode 13 protrudes from the first electrode layer 101 and second electrode layer 102 of the second auxiliary electrode 13 to form a second undercut structure 121 (shown in FIG. 4). Likewise, one end of the third electrode layer 103 of the third auxiliary electrode 15 protrudes from the first electrode layer 101 and second electrode layer 102 of the third auxiliary electrode 15 to form a third undercut structure 131 (shown in FIG. 4).

The first auxiliary electrode 11 has the first undercut structure 111, the second auxiliary electrode 13 has the second undercut structure 121, and the third auxiliary electrode 15 has the third undercut structure 131.

The first undercut structure 111 includes a first undercut groove 112, which includes a first sub-groove 1121 and a second sub-groove 1122 that are interconnected, and the first sub-groove 1121 is located between the third electrode layer 103, the first electrode layer 101 of the first auxiliary electrode 11, and the array substrate 110, while the second sub-groove 1122 is located between the third electrode layer 103 and the second electrode layer 102 of the first auxiliary electrode 11.

The second undercut structure 121 includes a second undercut groove 122, which includes a third sub-groove 1221 and a fourth sub-groove 1222 that are interconnected, and the third sub-groove 1221 is located between the third electrode layer 103, the first electrode layer 101 of the second auxiliary electrode 13, and the array substrate 110, while the fourth sub-groove 1222 is located between the third electrode layer 103 and the second electrode layer 102 of the second auxiliary electrode 13.

The third undercut structure 131 includes a third undercut groove 132, which includes a fifth sub-groove 1321 and a sixth sub-groove 1322 that are interconnected, and the fifth sub-groove 1321 is located between the third electrode layer 103, the first electrode layer 101 of the third auxiliary electrode 15, and the array substrate 110, while the sixth sub-groove 1322 is located between the third electrode layer 103 and the second electrode layer 102 of the third auxiliary electrode 15.

In some embodiments of this application, the array substrate 110 further includes a light-shielding layer 104 positioned away from the pixel defining layer 120 and a plurality of transistors 105 positioned between the light-shielding layer 104 and the first metal layer 10. The light-shielding layer 104 includes a plurality of first light-shielding portions 1041 and a plurality of second light-shielding portions 1042, and the transistors 105 are positioned between the light-shielding layer 104 and the first metal layer 10. The first auxiliary electrode 11, the second auxiliary electrode 13, and the third auxiliary electrode 15 are each connected to one first light-shielding portion 1041. The first anode 12, the second anode 14, and the third anode 16 are each connected to one transistor 105. The transistors 105 connected to the first anode 12, the second anode 14, and the third anode 16 are each connected to one second light-shielding portion 1042.

In some embodiments of this application, the array substrate 110 may further include film layers such as a substrate, and the transistor 105 may include an active layer, a gate layer, a source-drain layer, etc., which will not be described in detail here.

The pixel defining layer 120 is located on a side of the array substrate 110 and covers the first metal layer 10.

In some embodiments of this application, the pixel defining layer 120 includes a first auxiliary opening 21, a first pixel opening 22, a second auxiliary opening 23, a second pixel opening 24, a third auxiliary opening 25, and a third pixel opening 26. A part of the first auxiliary electrode 11 is exposed through the first auxiliary opening 21, and a part of the first anode 12 is exposed through the first pixel opening 22. A part of the second auxiliary electrode 13 is exposed through the second auxiliary opening 23, and a part of the second anode 14 is exposed through the second pixel opening 24. A part of the third auxiliary electrode 15 is exposed through the third auxiliary opening 25, and a part of the third anode 16 is exposed through the third pixel opening 26. The first auxiliary opening 21 is connected to the second sub-groove 1122 of the first undercut groove 112, the second auxiliary opening 23 is connected to the fourth sub-groove 1222 of the second undercut groove 122, and the third auxiliary opening 25 is connected to the sixth sub-groove 1322 of the third undercut groove 132.

The shielding layer 130 is located on a side of the pixel defining layer 120 away from the array substrate 110 and includes a first shielding unit 31, a second shielding unit 32, and a third shielding unit 33, which are spaced apart.

The first shielding unit 31 is positioned corresponding to the first light emitting unit 41 (described below) of the light emitting layer 140, breaks at the first auxiliary opening 21 and the first pixel opening 22, respectively, and is connected to the second electrode layer 102 of the first auxiliary electrode 11. The first shielding unit 31 is located on a surface of the pixel defining layer 120 away from the array substrate 110 and a side wall of the first auxiliary opening 21.

The second shielding unit 32 is positioned corresponding to the second light emitting unit 42 (described below) of the light emitting layer 140, breaks at the second auxiliary opening 23 and the second pixel opening 24, respectively, and is connected to the second electrode layer 102 of the second auxiliary electrode 13. The second shielding unit 32 is located on a surface of the pixel defining layer 120 away from the array substrate 110 and a side wall of the second auxiliary opening 23.

The third shielding unit 33 is positioned corresponding to the third light emitting unit 43 (described below) of the light emitting layer 140, breaks at the third auxiliary opening 25 and the third pixel opening 26, respectively, and is connected to the second electrode layer 102 of the third auxiliary electrode 15. The third shielding unit 33 is located on a surface of the pixel defining layer 120 away from the array substrate 110 and a side wall of the third auxiliary opening 25.

In some embodiments of this application, the shielding layer 130 is a single layer.

In some embodiments of this application, the shielding layer 130 is made of at least one material of the following materials: molybdenum titanium (MoTi) alloy, titanium (Ti), molybdenum (Mo), etc.

In some embodiments of this application, there are a first opening 34 located between the first shielding unit 31 and the second shielding unit 32, and a second opening 35 located between the second shielding unit 32 and the third shielding unit 33. The pixel defining layer 120 has a third opening 27 positioned corresponding to the first opening 34 and a fourth opening 28 positioned corresponding to the second opening 35.

The light emitting layer 140 is located on a side of the shielding layer 130 away from the pixel defining layer 120 and includes a first light emitting unit 41, a second light emitting unit 42, and a third light emitting unit 43, which are spaced apart. The first light emitting unit 41 is connected to the first anode 12 and the first auxiliary electrode 11, the second light emitting unit 42 is connected to the second anode 14 and the second auxiliary electrode 13, and the third light-emitting unit 43 is connected to the third anode 16 and the third auxiliary electrode 15.

In some embodiments of this application, the first light emitting unit 41 breaks at the first undercut structure 111 to form a first light emitting portion 411 and a second light emitting portion 412. The first light emitting portion 411 is positioned within the first sub-groove 1121 of the first undercut groove 112 and is connected to an end surface of the first electrode layer 101 of the first auxiliary electrode 11 facing the first sub-groove 1121 of the first undercut groove 112, a surface of the third electrode layer 103 of the first auxiliary electrode 11 protruding from the first electrode layer 101 and parallel to the array substrate 110, and a surface of the array substrate 110 exposed through the first undercut groove 112. The second light emitting portion 412 is located on a surface of the first shielding unit 31 away from the pixel defining layer 120 and is connected to surfaces of the second electrode layer 102 and the third electrode layer 103 of the first auxiliary electrode 11 parallel to the array substrate 110.

In some embodiments of this application, the second light emitting unit 42 breaks at the second undercut structure 121 to form a third light emitting portion 421 and a fourth light emitting portion 422. The third light emitting portion 421 is positioned within the third sub-groove 1221 of the second undercut groove 122 and is connected to an end surface of the first electrode layer 101 of the second auxiliary electrode 13 facing the third sub-groove 1221 of the second undercut groove 122, a surface of the third electrode layer 103 of the second auxiliary electrode 13 protruding from the first electrode layer 101 and parallel to the array substrate 110, and a surface of the array substrate 110 exposed through the second undercut groove 122. The fourth light emitting portion 422 is located on a surface of the second shielding unit 32 away from the pixel defining layer 120 and is connected to surfaces of the second electrode layer 102 and the third electrode layer 103 of the second auxiliary electrode 13 parallel to the array substrate 110.

In some embodiments of this application, the third light emitting unit 43 breaks at the third undercut structure 131 to form a fifth light emitting portion 431 and a sixth light emitting portion 432. The fifth light-emitting part 431 is positioned within the fifth sub-groove 1321 of the third undercut groove 132 and is connected to an end surface of the first electrode layer 101 of the third auxiliary electrode 15 facing the fifth sub-groove 1321 of the third undercut groove 132, a surface of the third electrode layer 103 of the third auxiliary electrode 15 protruding from the first electrode layer 101 and parallel to the array substrate 110 and a surface of the array substrate 110 exposed from the third undercut groove 132. The sixth light emitting portion 432 is located on a surface of the third shielding unit 33 away from the pixel defining layer 120 and is connected to surfaces of the second electrode layer 102 and the third electrode layer 103 of the third auxiliary electrode 15 parallel to the array substrate 110.

In some embodiments of this application, there are a first gap 401 located between the first light emitting unit 41 and the second light emitting unit 42, and a second gap 402 located between the second light emitting unit 42 and the third light emitting unit 43, and the cathode (described below) breaks at the first gap 401 and the second gap 402. The third opening 27 of the pixel defining layer 120, the first opening 34 of the shielding layer 130, and the first gap 401 of the light emitting layer 140 are positioned correspondingly, and the fourth opening 28 of the pixel defining layer 120, the second opening 35 of the shielding layer 130, and the second gap 402 of the light emitting layer 140 are positioned correspondingly.

The second metal layer 150 is located on a side of the light emitting layer 140 away from the shielding layer 130 and includes a cathode 50. The cathode 50 includes a first cathode portion 51, a second cathode portion 52, and a third cathode portion 53. The first cathode portion 51 covers the first light emitting unit 41, the second cathode portion 52 covers the second light emitting unit 42, and the third cathode portion 53 covers the third light emitting unit 43. The first cathode portion 51 is continuous at the first undercut structure 111, the second cathode portion 52 is continuous at the second undercut structure 121, and the third cathode portion 53 is continuous at the third undercut structure 131.

In some embodiments of this application, the first cathode portion 51 is connected to an end surface of the third electrode layer 103 of the first undercut structure 111 facing the first undercut groove 112, the second cathode portion 52 is connected to an end surface of the third electrode layer 103 of the second undercut structure 121 facing the second undercut groove 122, and the third cathode portion 53 is connected to an end surface of the third electrode layer 103 of the third undercut structure 131 facing the third undercut groove 132.

The first cathode portion 51 is connected to the first light emitting unit 41 but is not connected to the first shielding unit 31, the second cathode portion 52 is connected to the second light emitting unit 42 but is not connected to the second shielding unit 32, and the third cathode portion 53 is connected to the third light emitting unit 43 but is not connected to the third shielding unit 33.

The display panel 100 further includes an encapsulation layer 160 covering the second metal layer 150 and filling the first gap 401, the first opening 34, the third opening 27, the second gap 402, the second opening 35, and the fourth opening 28.

Referring to FIGS. 1 to 7, this application further provides a method for preparing a display panel, including:

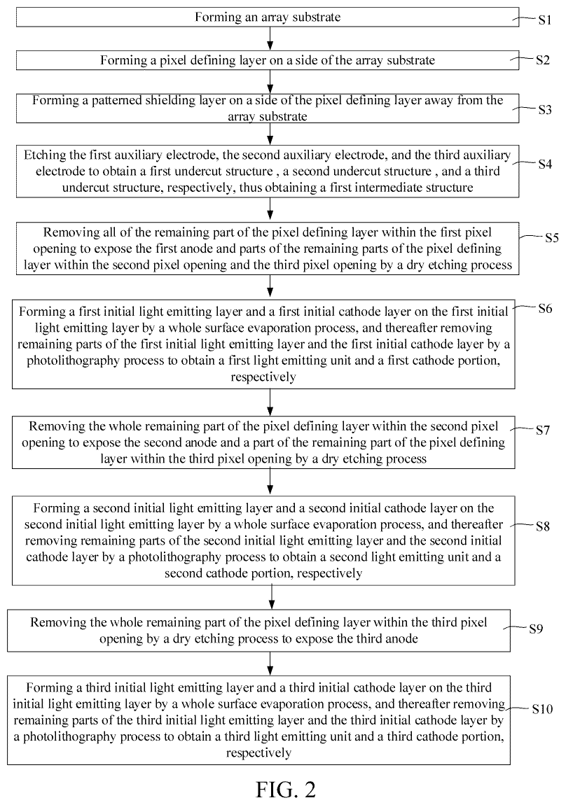

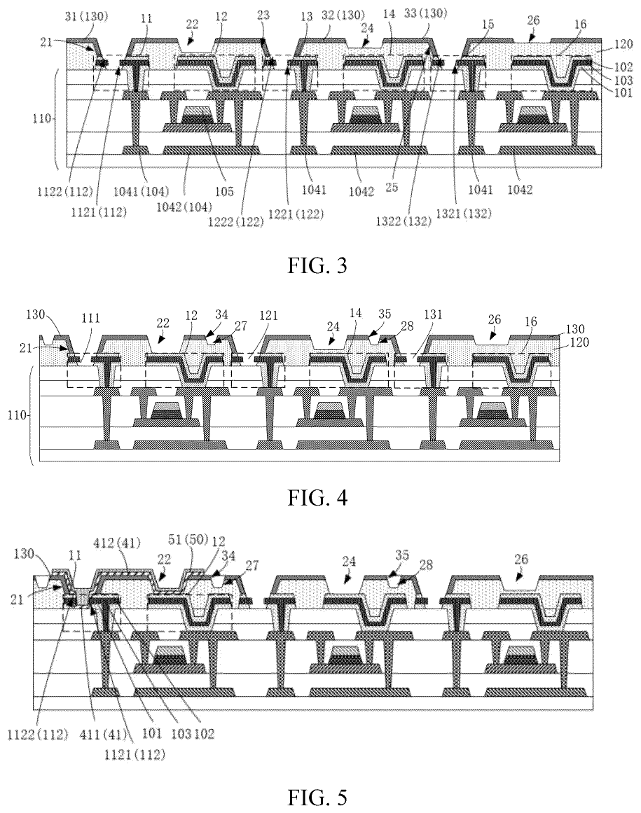

Step S1, please refer to FIGS. 2 to 3, forming an array substrate 110.

The array substrate 110 includes a first metal layer 10, which includes a first auxiliary electrode 11, a first anode 12 located on a side of the first auxiliary electrode 11, a second auxiliary electrode 13, a second anode 14 located on a side of the second auxiliary electrode 13, a third auxiliary electrode 15, and a third anode 16 located on a side of the third auxiliary electrode 15.

The first metal layer 10 includes a first electrode layer 101, a second electrode layer 102, and a third electrode layer 103 located between the first electrode layer 101 and the second electrode layer 102. The first electrode layer 101, the second electrode layer 102, and the third electrode layer 103 are stacked in sequence in a stacking direction of the array substrate 110 and a pixel defining layer 120.

The material of the first electrode layer 101 and the material of the second electrode layer 102 may be the same or different from each other; however, the material of the first electrode layer 101 and the material of the second electrode layer 102 are both different from the material of the third electrode layer 103.

Step S2, please refer to FIGS. 2 to 3, forming the pixel defining layer 120 on a side of the array substrate 110.

The pixel defining layer 120 covers the first metal layer 10 and includes a first auxiliary opening 21, a first pixel opening 22, a second auxiliary opening 23, a second pixel opening 24, a third auxiliary opening 25, and a third pixel opening 26. Part of the first auxiliary electrode 11, part of the second auxiliary electrode 13, and part of the third auxiliary electrode 15 are exposed through the first auxiliary opening 21, the second auxiliary opening 23, and the third auxiliary opening 25, respectively. Remaining parts of the pixel defining layer 120 located in the first pixel opening 22, the second pixel opening 24, and the third pixel opening 26 cover the first anode 12, the second anode 14, and the third anode 16, respectively.

A thickness of the remaining part of the pixel defining layer within the first pixel opening 22, a thickness of the remaining part of the pixel defining layer within the second pixel opening 24, and a thickness of the remaining part of the pixel defining layer within the third pixel opening 26 increase in sequence along the stacking direction of the pixel defining layer 120 and the array substrate 110.

Step S3, please refer to FIGS. 2 to 3, forming a patterned shielding layer 130 on a side of the pixel defining layer 120 away from the array substrate 110.

Part of the first auxiliary electrode 11, part of the second auxiliary electrode 13, and part of the third auxiliary electrode 15 are exposed through the shielding layer 130, respectively.

The shielding layer 130 can function as an isolation barrier during subsequent dry etching processes to remove the remaining parts of the pixel defining layer 120 within the first pixel opening 22, the second pixel opening 24, and the third pixel opening 26, respectively, to protect the pixel defining layer 120 and the first metal layer 10 in other locations, preventing them from being etched or damaged simultaneously.

The shielding layer 130 includes a first shielding unit 31, a second shielding unit 32, and a third shielding unit 33, which are spaced apart. The first shielding unit 31 is positioned corresponding to the first auxiliary electrode 11 and the first anode 12, the second shielding unit 32 is positioned corresponding to the second auxiliary electrode 13 and the second anode 14, and the third shielding unit 33 is positioned corresponding to the third auxiliary electrode 15 and the third anode 16. The first shielding unit 31 is located on a surface of the pixel defining layer 120 away from the array substrate 110 and a side wall of the first auxiliary opening 21. The second shielding unit 32 is located on the surface of the pixel defining layer 120 away from the array substrate 110 and a side wall of the second auxiliary opening 23. The third shielding unit 33 is located on the surface of the pixel defining layer 120 away from the array substrate 110 and a side wall of the third auxiliary opening 25.

There are a first opening 34 located between the first shielding unit 31 and the second shielding unit 32, and a second opening 35 located between the second shielding unit 32 and the third shielding unit 33. A third opening 27 is positioned corresponding to the first opening 34, and a fourth opening 28 is positioned corresponding to the second opening 35.

Step S4, please refer to FIGS. 2 to 3, etching the first auxiliary electrode 11, the second auxiliary electrode 13, and the third auxiliary electrode 15 to obtain a first undercut structure 111, a second undercut structure 121, and a third undercut structure 131, respectively, and thus obtaining a first intermediate structure 1001.

In some embodiments of this application, an auxiliary electrode can be etched by using an acid capable of etching silver, firstly; thereafter the auxiliary electrode can be etched by using an acid capable of etching indium tin oxide (ITO), thereby an undercut structure with the third electrode layer 103 protruding from the first electrode layer 101 and the second electrode layer can be formed without additional process steps.

The first auxiliary electrode 11 includes a first undercut groove 112. The first undercut groove 112 includes a first sub-groove 1121 and a second sub-groove 1122 that are interconnected, and the first sub-groove 1121 is located between the third electrode layer 103, the first electrode layer 101 of the first auxiliary electrode 11, and the array substrate 110, while the second sub-groove 1122 is located between the third electrode layer 103 and the second electrode layer 102 of the first auxiliary electrode 11.

The second auxiliary electrode 13 includes a second undercut groove 122. The second undercut groove 122 includes a third sub-groove 1221 and a fourth sub-groove 1222 that are interconnected, and the third sub-groove 1221 is located between the third electrode layer 103, the first electrode layer 101 of the second auxiliary electrode 13, and the array substrate 110, while the fourth sub-groove 1222 is located between the third electrode layer 103 and the second electrode layer 102 of the second auxiliary electrode 13.

The third auxiliary electrode 15 includes a third undercut groove 132. The third undercut groove 132 includes a fifth sub-groove 1321 and a sixth sub-groove 1322 that are interconnected, and the fifth sub-groove 1321 is located between the third electrode layer 103, the first electrode layer 101 of the third auxiliary electrode 15, and the array substrate 110, while the sixth sub-groove 1322 is located between the third electrode layer 103 and the second electrode layer 102 of the third auxiliary electrode 15.

Step S5, please refer to FIGS. 2 and 4, removing all of the remaining part of the pixel defining layer 120 within the first pixel opening 22 to expose the first anode 12 and parts of the remaining parts of the pixel defining layer 120 within the second pixel opening 24 and the third pixel opening 26 by a dry etching process.

The rest of the remaining part of the pixel defining layer 120 within the second pixel opening 24 covers the second anode 14, and the rest of the remaining part of the pixel defining layer 120 within the third pixel opening 26 covers the third anode 16.

After the step S5, in the stacking direction of the pixel defining layer 120 and the array substrate 110, the thickness of the remaining part of the pixel defining layer 120 within the second pixel opening 24 is smaller than the thickness of the remaining part of the pixel definition layer 120 within the third pixel opening 26.

Step S6, please refer to FIGS. 2 and 5, forming a first initial light emitting layer and a first initial cathode layer on the first initial light emitting layer by a whole surface evaporation process, and thereafter removing remaining parts of the first initial light emitting layer and the first initial cathode layer by a photolithography process to obtain a first light emitting unit 41 and a first cathode portion 51, respectively.

The first light emitting unit 41 is connected to the first anode 12 and the first auxiliary electrode 11, respectively, and breaks at the first undercut structure 111. The first cathode portion 51 is connected to the first auxiliary electrode 11.

The first cathode portion 51 and the first shielding unit 31 are not connected to each other.

Step S7, please refer to FIGS. 2 and 5, removing the whole remaining part of the pixel defining layer 120 within the second pixel opening 24 to expose the second anode 14 and a part of the remaining part of the pixel defining layer 120 within the third pixel opening 26 by a dry etching process.

A thickness of the rest of the pixel defining layer 120 within the third pixel opening 26 in the stacking direction of the pixel defining layer 120 and the array substrate 110 is greater than 0.

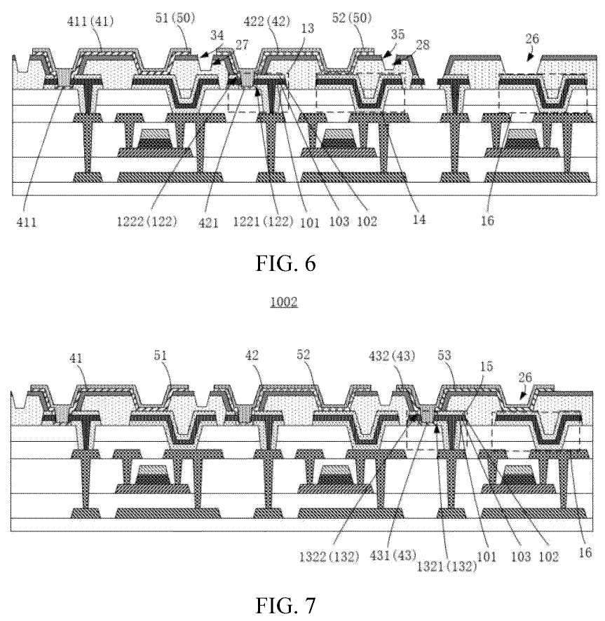

Step S8, please refer to FIGS. 2 and 6, forming a second initial light emitting layer and a second initial cathode layer on the second initial light emitting layer by a whole surface evaporation process, and thereafter removing remaining parts of the second initial light emitting layer and the second initial cathode layer by a photolithography process to obtain a second light emitting unit 42 and a second cathode portion 52, respectively.

The second light emitting unit 42 is connected to the second anode 14 and the second auxiliary electrode 13, respectively, and breaks at the second undercut structure 121. The second cathode portion 52 is connected to the second auxiliary electrode 13.

The second cathode portion 52 and the second shielding unit 32 are not connected to each other.

There is a first gap 401 located between the first light emitting unit 41 and the second light emitting unit 42, and a cathode 50 (described below) breaks at the first gap 401.

Step S9, please refer to FIGS. 2 and 6, removing the whole remaining part of the pixel defining layer 120 within the third pixel opening 26 by a dry etching process to expose the third anode 16.

Step S10, please refer to FIGS. 2 and 7, forming a third initial light emitting layer and a third initial cathode layer on the third initial light emitting layer by a whole surface evaporation process, and thereafter removing remaining parts of the third initial light emitting layer and the third initial cathode layer by a photolithography process to obtain a third light emitting unit 43 and a third cathode portion 53, respectively.

The third light emitting unit 43 is connected to the third anode 16 and the third auxiliary electrode 15, respectively, and breaks at the third undercut structure 131. The third cathode portion 53 is connected to the third auxiliary electrode 15, thus forming a second intermediate structure 1002.

The first cathode portion 51, the second cathode portion 52, and the third cathode portion 53 compose the cathode 50 and the second metal layer 150, or a part of the cathode 50 and the second metal layer 150. The first light emitting unit 41, the second light emitting unit 42, and the third light emitting unit 43 compose the light emitting layer 140, or a part of the light emitting layer 140.

There is a second gap 402 located between the second light emitting unit 42 and the third light emitting unit 43, and the cathode breaks at the second gap 402.

The first cathode portion 51 and the first light emitting unit 41 correspond to a first sub-pixel; similarly, the second cathode portion 52 and the second light emitting unit 42 correspond to a second sub-pixel, and the third cathode portion 53 and the third light emitting unit 43 correspond to a third sub-pixel. The first sub-pixel, the second sub-pixel, and the third sub-pixel are sub-pixels of different colors. That is, the first light emitting unit 41, the second light emitting unit 42, and the third light emitting unit 43 emit light of different colors. In this embodiment, the first sub-pixel, the second sub-pixel, and the third sub-pixel are one of a red sub-pixel, a green sub-pixel, and a blue sub-pixel, respectively. In other embodiments, sub-pixels of other colors may also be included, and accordingly, the display panel can also include additional light-emitting units and cathode portions.

The third cathode portion 53 and the third shielding unit 33 are not connected to each other.

The pixel defining layer 120 has a third opening 27 and a fourth opening 28. The third opening 27 is positioned corresponding to the first opening 34 and the first gap 401, and the fourth opening 28 is positioned corresponding to the second opening 35 and the second gap 402. The third opening 27 and the fourth opening 28 are formed simultaneously when the remaining parts of the pixel defining layer 120 within the first pixel opening 22, the second pixel opening 24, and the third pixel opening 26 are etched by the dry etching processes.

After the step S10, please refer to FIG. 1, the method further includes a step of forming an encapsulation layer 160 which covers the second metal layer 150 and fills the first gap 401, the first opening 34, the third opening 27, the second gap 402, the second opening 35, and the fourth opening 28.

The encapsulation layer 160 is used to protect the cathode 50 and the light emitting layer 140 and isolate moisture. The encapsulation layer 160 is filled in the first gap 401, the first opening 34, the third opening 27, the second gap 402, the second opening 35, and the fourth opening 28 to disconnect each light emitting unit, which can avoid an intrusion of water and oxygen and a light mixing generated in the area between adjacent sub-pixels that could lead to an abnormal display of the display panel.

This application also provides a display device (not shown), which includes the display panel 100 mentioned above. The display device may be an electronic product, such as a smart bracelet, a smart watch, a smart phone, a tablet, a laptop, a desktop computer, a television, etc.

This application provides a display panel, a method for preparing a display panel and a display device. The display panel includes: an array substrate including a first metal layer, and the first metal layer includes a first auxiliary electrode, and a first anode located on a side of the first auxiliary electrode; a pixel defining layer located on a side of the array substrate and covering the first metal layer, and the pixel defining layer includes a first auxiliary opening and a first pixel opening, a part of the first auxiliary electrode is exposed through the first auxiliary opening, and a part of the first anode is exposed through the first pixel opening; a light emitting layer including a first light emitting unit and located on a side of the pixel defining layer away from the array substrate, with the first light emitting unit being connected to the first anode and the first auxiliary electrode, respectively; a second metal layer including a cathode that is located on a side of the light emitting layer away from the pixel defining layer; and a shielding layer located between the pixel defining layer and the light emitting layer, wherein the shielding layer is connected to the first light emitting unit but is not connected to the cathode. The first auxiliary electrode has a first undercut structure positioned corresponding to the first auxiliary opening, and the first light emitting unit breaks at the first undercut structure. In this application, arranging a patterned shielding layer between the pixel defining layer and the light emitting layer is helpful to protect the pixel defining layer and allow to form a first initial light emitting layer by a whole surface evaporation process firstly, and then remove a redundant part of the initial light emitting layer by a photolithography process when forming a light emitting unit (for example, the first light emitting unit) corresponding to a sub-pixel, thereby obtaining the light emitting unit (for example, the first light emitting unit) corresponding to the sub-pixel. In this application, in the process of obtaining the light emitting unit (for example, the first light emitting unit) corresponding to the sub-pixel, it is not necessary to separately evaporate and form red, blue, and green sub-pixels by multiple fine metal mask processes, thus circumventing limitations imposed by the size and precision of a mask plate, which can solve the problem of the evaporation of the large-size OLED and produce display panels with high pixel density.

In addition, in this application, since the light emitting units are formed separately, during a process of forming the first light emitting unit, anodes corresponding to other pixels are protected by remaining parts of the pixel defining layer within pixel openings. When light emitting units corresponding to other pixels need to be formed, the remaining parts of the pixel defining layer within pixel openings are removed by dry etching processes, which are simple, convenient to operate and low in cost.

In addition, the patterned shielding layer is used and breaks at undercut structures. The shielding layer does not need to compose the undercut structures, and a combination of the shielding layer and the remaining parts of the pixel defining layer within the pixel openings can form different light emitting units separately, cathode portions and overlaps of the cathode, which are simple, convenient to operate and low in cost.

In addition, because an auxiliary electrode (for example, the first auxiliary electrode) has an undercut structure, and both the shielding layer and the light emitting layer break at the undercut structure, while the cathode is continuous at the undercut structure and connects (edge contact) with a side surface (end surface) of the auxiliary electrode, under a power-on condition, a certain amount of Ag can migrate (Ag ions on the auxiliary electrode can migrate to the cathode), which can reduce an impedance of the cathode and make the cathode and the auxiliary electrode connected better.

A display panel and a display device provided in the embodiments of this application are described in detail above, and specific examples are used to illustrate the principles and implementations of the present application. The descriptions of the above-mentioned embodiments are only used to help understand technical solutions and core ideas of this application; persons of ordinary skill in the art should understand that they may still make modifications to the technical solutions described in the foregoing embodiments or make equivalent replacements to some or all technical features thereof, without departing from the scope of the technical solutions of the embodiments of the present application.

What is claimed is:

1. A display panel, wherein the display panel comprising:
an array substrate comprising a first metal layer, wherein the first metal layer comprises a first auxiliary electrode and a first anode located on a side of the first auxiliary electrode;
a pixel defining layer located on a side of the array substrate and covering the first metal layer, wherein the pixel defining layer comprises a first auxiliary opening and a first pixel opening, a part of the first auxiliary electrode is exposed through the first auxiliary opening, and a part of the first anode is exposed through the first pixel opening;
a light emitting layer comprising a first light emitting unit and located on a side of the pixel defining layer away from the array substrate, wherein the first light emitting unit connects to the first anode and the first auxiliary electrode, respectively;
a second metal layer comprising a cathode, wherein the cathode is located on a side of the light emitting layer away from the pixel defining layer; and
a shielding layer located between the pixel defining layer and the light emitting layer, wherein the shielding layer connects to the first light emitting unit but does not connect to the cathode;
wherein the first auxiliary electrode comprises a first undercut structure positioned corresponding to the first auxiliary opening, and the first light emitting unit breaks at the first undercut structure.

2. The display panel of claim 1, wherein
the first metal layer further comprises a second auxiliary electrode and a second anode located on a side of the second auxiliary electrode;
the pixel defining layer further comprises a second auxiliary opening and a second pixel opening, a part of the second auxiliary electrode is exposed through the second auxiliary opening, and a part of the second anode is exposed through the second pixel opening;
the light emitting layer further comprises a second light emitting unit spaced apart from the first light emitting unit and connected to the second anode and the second auxiliary electrode, respectively; and
the second auxiliary electrode comprises a second undercut structure positioned corresponding to the second auxiliary opening, and the second light emitting unit breaks at the second undercut structure.

3. The display panel of claim 2, wherein
the first metal layer further comprises a third auxiliary electrode and a third anode located on a side of the third auxiliary electrode;
the pixel defining layer further comprises a third auxiliary opening and a third pixel opening, a part of the third auxiliary electrode is exposed through the third auxiliary opening, and a part of the third anode is exposed through the third pixel opening;
the light emitting layer further comprises a third light emitting unit spaced apart from the second light emitting unit and connected to the third anode and the third auxiliary electrode, respectively; and
the third auxiliary electrode comprises a third undercut structure positioned corresponding to the third auxiliary opening, and the third light emitting unit breaks at the third undercut structure.

4. The display panel of claim 3, wherein the shielding layer comprises a first shielding unit located between the pixel defining layer and the first light emitting unit, wherein the first shielding unit breaks at the first auxiliary opening and the first pixel opening, respectively, and connects to the first auxiliary electrode, and the first shielding unit connects to the first light emitting unit but does not connect to the cathode.

5. The display panel of claim 4, wherein the shielding layer further comprises:
a second shielding unit located between the pixel defining layer and the second light emitting unit and spaced apart from the first shielding unit, wherein the second shielding unit breaks at the second auxiliary opening and the second pixel opening, respectively, and connects to the second auxiliary electrode, and the second shielding unit connects to the second light emitting unit but does not connect to the cathode; and
a third shielding unit located between the pixel defining layer and the third light emitting unit and spaced apart from the second shielding unit, wherein the third shielding unit breaks at the third auxiliary opening and the third pixel opening, respectively, and connects to the third auxiliary electrode, and the third shielding unit connects to the third light emitting unit but does not connect to the cathode.

6. The display panel of claim 5, wherein
a first gap is located between the first light emitting unit and the second light emitting unit and a second gap is located between the second light emitting unit and the third light emitting unit, and the cathode breaks at the first gap and the second gap;
a first opening is located between the first shielding unit and the second shielding unit and a second opening is located between the second shielding unit and the third shielding unit; and
the pixel defining layer has a third opening positioned corresponding to the first opening and the first gap and a fourth opening positioned corresponding to the second opening and the second gap.

7. The display panel of claim 6, wherein the display panel further comprises an encapsulation layer covering the second metal layer and filling the first gap, the first opening, the third opening, the second gap, the second opening, and the fourth opening.

8. The display panel of claim 1, wherein
the first auxiliary electrode comprises a first electrode layer, a second electrode layer, and a third electrode layer located between the first electrode layer and the second electrode layer, which are stacked in sequence in a stacking direction of the array substrate and the pixel defining layer; and
one end of the third electrode layer protrudes from the first electrode layer and the second electrode layer at the first auxiliary opening.

9. The display panel of claim 8, wherein
the first auxiliary electrode has a first undercut groove which comprises a first sub-groove and a second sub-groove that are interconnected, the first sub-groove is located between the third electrode layer, the first electrode layer, and the array substrate, and the second sub-groove is located between the third electrode layer and the second electrode layer; and
the first light emitting unit comprises a first light emitting portion and a second light emitting portion, the first light emitting portion is located within the first sub-groove and connects to the array substrate, the first electrode layer, and the third electrode layer, respectively, a part of the second light emitting portion is located on a side of the shielding layer away from the pixel defining layer, and another part of the second light emitting portion is located within the second sub-groove and connects to the shielding layer, the second electrode layer, and the third electrode layer, respectively.

10. The display panel of claim 6, wherein
the cathode comprises a first cathode portion, a second cathode portion, and a third cathode portion, the first, second, and third cathode portions cover the first, second, and third light emitting units, respectively; and
the first cathode portion is continuous at the first undercut structure, the second cathode portion is continuous at the second undercut structure, and the third cathode portion is continuous at the third undercut structure.

11. The display panel of claim 3, wherein the array substrate further comprises:
a light-shielding layer comprising a plurality of light-shielding portions; and
a plurality of transistors located between the light-shielding layer and the first metal layer;
wherein the first anode, the second anode, and the third anode are each connected to one transistor;
the first auxiliary electrode, the second auxiliary electrode, and the third auxiliary electrode are each connected to one light-shielding portion, and
the transistors connected to the first, second, and third anodes are each connected to one light-shielding portion.

12. A display device comprising:
a display panel; the display panel comprising:
an array substrate comprising a first metal layer, wherein the first metal layer comprises a first auxiliary electrode and a first anode located on a side of the first auxiliary electrode;
a pixel defining layer located on a side of the array substrate and covering the first metal layer, wherein the pixel defining layer comprises a first auxiliary opening and a first pixel opening, a part of the first auxiliary electrode is exposed through the first auxiliary opening, and a part of the first anode is exposed through the first pixel opening;
a light emitting layer comprising a first light emitting unit and located on a side of the pixel defining layer away from the array substrate, wherein the first light emitting unit connects to the first anode and the first auxiliary electrode, respectively;
a second metal layer comprising a cathode, wherein the cathode is located on a side of the light emitting layer away from the pixel defining layer; and
a shielding layer located between the pixel defining layer and the light emitting layer, wherein the shielding layer connects to the first light emitting unit but does not connect to the cathode;
wherein the first auxiliary electrode comprises a first undercut structure positioned corresponding to the first auxiliary opening, and the first light emitting unit breaks at the first undercut structure.

13. The display device of claim 12, wherein
the first metal layer further comprises a second auxiliary electrode and a second anode located on a side of the second auxiliary electrode;
the pixel defining layer further comprises a second auxiliary opening and a second pixel opening, a part of the second auxiliary electrode is exposed through the second auxiliary opening, and a part of the second anode is exposed through the second pixel opening;
the light emitting layer further comprises a second light emitting unit spaced apart from the first light emitting unit and connected to the second anode and the second auxiliary electrode, respectively; and
the second auxiliary electrode comprises a second undercut structure positioned corresponding to the second auxiliary opening, and the second light emitting unit breaks at the second undercut structure.

14. The display device of claim 13, wherein
the first metal layer further comprises a third auxiliary electrode and a third anode located on a side of the third auxiliary electrode;
the pixel defining layer further comprises a third auxiliary opening and a third pixel opening, a part of the third auxiliary electrode is exposed through the third auxiliary opening, and a part of the third anode is exposed through the third pixel opening;
the light emitting layer further comprises a third light emitting unit spaced apart from the second light emitting unit and connected to the third anode and the third auxiliary electrode, respectively; and
the third auxiliary electrode comprises a third undercut structure positioned corresponding to the third auxiliary opening, and the third light emitting unit breaks at the third undercut structure.

15. The display device of claim 14, wherein the shielding layer comprises a first shielding unit located between the pixel defining layer and the first light emitting unit, wherein the first shielding unit breaks at the first auxiliary opening and the first pixel opening, respectively, and connects to the first auxiliary electrode, and the first shielding unit connects to the first light emitting unit but does not connect to the cathode.

16. The display device of claim 15, wherein the shielding layer further comprises:
a second shielding unit located between the pixel defining layer and the second light emitting unit and spaced apart from the first shielding unit, wherein the second shielding unit breaks at the second auxiliary opening and the second pixel opening, respectively, and connects to the second auxiliary electrode, and the second shielding unit connects to the second light emitting unit but does not connect to the cathode; and
a third shielding unit located between the pixel defining layer and the third light emitting unit and spaced apart from the second shielding unit, wherein the third shielding unit breaks at the third auxiliary opening and the third pixel opening, respectively, and connects to the third auxiliary electrode, and the third shielding unit connects to the third light emitting unit but does not connect to the cathode.

17. The display device of claim 16, wherein
a first gap is located between the first light emitting unit and the second light emitting unit and a second gap is located between the second light emitting unit and the third light emitting unit, and the cathode breaks at the first gap and the second gap;
a first opening is located between the first shielding unit and the second shielding unit and a second opening is located between the second shielding unit and the third shielding unit; and
the pixel defining layer has a third opening positioned corresponding to the first opening and the first gap and a fourth opening positioned corresponding to the second opening and the second gap.

18. The display device of claim 17, wherein the display panel further comprises an encapsulation layer covering the second metal layer and filling the first gap, the first opening, the third opening, the second gap, the second opening, and the fourth opening.

19. The display device of claim 12, wherein
the first auxiliary electrode comprises a first electrode layer, a second electrode layer, and a third electrode layer located between the first electrode layer and the second electrode layer, which are stacked in sequence in a stacking direction of the array substrate and the pixel defining layer; and
one end of the third electrode layer protrudes from the first electrode layer and the second electrode layer at the first auxiliary opening.

20. A method for preparing a display panel comprising:
forming an array substrate, wherein the array substrate comprises a first metal layer, and the first metal layer comprises a first auxiliary electrode, a first anode located on a side of the first auxiliary electrode, a second auxiliary electrode, and a second anode located on a side of the second auxiliary electrode;
forming a pixel defining layer on a side of the array substrate, wherein the pixel defining layer covers the first metal layer and comprises a first auxiliary opening, a first pixel opening, a second auxiliary opening, and a second pixel opening, parts of the first auxiliary electrode and the second auxiliary electrode are exposed through the first auxiliary opening and the second auxiliary opening, respectively, and remaining parts of the pixel defining layer within the first pixel opening and the second pixel opening cover the first anode and the second anode, respectively;
forming a patterned shielding layer on a side of the pixel defining layer away from the array substrate, wherein parts of the first auxiliary electrode and the second auxiliary electrode are exposed through the shielding layer;
etching the first auxiliary electrode and the second auxiliary electrode, respectively, to obtain a first undercut structure and a second undercut structure;
removing all of the remaining parts of the pixel defining layer within the first pixel opening to expose the first anode and a part of the remaining parts of the pixel defining layer within the second pixel opening by a dry etching process, wherein the rest of the remaining parts of the pixel defining layer within the second pixel opening covers the second anode;
forming a first initial light emitting layer and a first initial cathode layer on the first initial light emitting layer by a whole surface evaporation process, and removing remaining parts of the first initial light emitting layer and the first initial cathode layer by a photolithography process to obtain a first light emitting unit and a first cathode portion, respectively, wherein the first light emitting unit is connected to the first anode and the first auxiliary electrode, respectively, and breaks at the first undercut structure, and the first cathode portion is connected to the first auxiliary electrode;
removing the whole remaining parts of the pixel defining layer within the second pixel opening to expose the second anode by a dry etching process; and
forming a second initial light emitting layer and a second initial cathode layer on the second initial light emitting layer by a whole surface evaporation process, and removing remaining parts of the second initial light emitting layer and the second initial cathode layer by a photolithography process to obtain a second light emitting unit and a second cathode portion, respectively, wherein the second light emitting unit is connected to the second anode and the second auxiliary electrode, respectively, and breaks at the second undercut structure, and the second cathode portion is connected to the second auxiliary electrode.
